(19) United States
(12) Patent Application Publication
(10) Pub. No.: US 2024/0120672 A1
(43) Pub. Date: Apr. 11, 2024

(54) ELECTRICAL CONNECTOR

(71) Applicant: Tarng Yu Enterprise co., ltd., New Taipei City (TW)

(72) Inventors: YING-CHUNG CHEN, New Taipei City (TW); MU-JUNG HUANG, New Taipei City (TW)

(21) Appl. No.: 18/377,301

(22) Filed: Oct. 5, 2023

(30) Foreign Application Priority Data
Oct. 6, 2022 (TW) 111138103

(51) Int. Cl. H01R 12/72; H01R 13/6587

(52) U.S. Cl. CPC H01R 12/727; H01R 13/6587

(57) ABSTRACT

A type of electrical connector that replaces the use of a conductive wire with a circuit board for transmitting signals to allow the conductive component of the electrical connector to transmit signals without relying on the conductive wire, addressing the known issue of difficulties in securely positioning the conductive component relative to the conductive wire during the electrical connector manufacturing. This innovation enables automated production of the electrical connector, consequently reducing production costs of the electrical connector.

### CROSS-REFERENCE TO RELATED APPLICATIONS

This application claims the priority of Republic of China Patent Application No. 111138103 filed on Oct. 6, 2022, in the State Intellectual Property Office of the R.O.C., the disclosure of which is incorporated herein by reference.

### BACKGROUND OF THE INVENTION

### Field of the Invention

The present invention relates to an electrical connector, particularly to an electrical connector that utilizes a circuit board to transmit signals.

### Descriptions of the Related Art

Current electrical connectors often need to electrically connect conductive components to conductive wires to transmit signals. However, how to fix the relative position of the conductive components and the conductive wires is a problem that needs to be faced when manufacturing the electrical connector. Furthermore, there are various structural forms of electrical connectors. For example, FAKRA electrical connectors used in equipment, such as vehicle equipment, mobile communication equipment, and telecommunication equipment, etc., usually need to weld conductive components to the conductive wires, so that the conductive components of the FAKRA electrical connectors are electrically connected to the conductive wires of the FAKRA electrical connectors. However, since the relative position of the conductive components and the conductive wires are not easy to fix, the FAKRA electrical connector is not conducive to automatic manufacturing and the manufacturing cost of the FAKRA electrical connector remains high.

Accordingly, how to make the conductive components of the electrical connector transmit signals without passing through the conductive wires has become a problem that the relevant industry is trying to solve.

### SUMMARY OF THE INVENTION

Given the shortcomings of the above-mentioned prior art, the present invention provides an electrical connector. The electrical connector is used for joining a joining component and transmitting a non-grounded signal to the joining component. The electrical connector comprises: an internal terminal, which includes an internal terminal joining structure and an internal terminal transmitting structure; circuit board, consisting of a circuit board body and a non-grounded circuit layer. The internal terminal joining structure is responsible for joining the joining component, and the internal terminal transmitting structure is electrically connected to the non-grounded circuit layer and the internal terminal joining structure respectively to allow the non-grounded signal to be transmitted to the joining component through the non-grounded circuit layer and the internal terminal joining structure.

Preferably, in the electrical connector said above, the electrical connector can also transmit a grounded signal to the joining component. Additionally, the circuit board includes a grounded circuit layer. The electrical connector further comprises: an external terminal, which consists of an external terminal joining structure and an external terminal transmitting structure. The external terminal joining structure is responsible for joining the joining component. The external terminal transmitting structure is electrically connected to the grounded circuit layer and the external terminal joining structure respectively, allowing the grounded signal to be transmitted to the joining component through the grounded circuit layer and the external terminal joining structure.

Preferably, in the electrical connector said above, the non-grounded circuit layer is located on the inner layer of the circuit board body, while the grounded circuit layer is positioned on the outer layer of the circuit board body to allow the grounded circuit layer to provide electrical shielding for the signal transmission of the non-grounded circuit layer.

Preferably, in the electrical connector said above, the external terminal also includes an external terminal shielding structure, which serves to shield the internal terminal transmitting structure to allow the external terminal shielding structure to provide electrical shielding for the signal transmission of the internal terminal transmitting structure.

Preferably, in the electrical connector said above, the external terminal shielding structure is a U-shaped structure and can shield the internal terminal transmitting structure in three directions.

Preferably, in the electrical connector said above, the external terminal also includes an external terminal bending structure and an external terminal body. The external terminal bending structure is positioned on the external terminal body and can bend the external terminal body to form the external terminal shielding structure.

Preferably, in the electrical connector said above, further includes: a connector housing, at least one conductive component, and a plug-in component. The conductive component, the plugin, and the circuit board are respectively plugged into the connector housing. The conductive component has the internal terminal and the external terminal. The plugin has a plugin positioning structure, which is embedded in the conductive component and positioned in the connector housing.

Preferably, in the electrical connector said above, the at least one conductive component is a plurality of conductive components, and the plugin is embedded within the plurality of conductive components, wherein the plugin positions and separates the plurality of conductive components within the connector housing.

Preferably, in the electrical connector said above, the conductive component has a conductive component housing, which separates the internal terminal and the external terminal. The plugin positioning structure is embedded within the conductive component housing and positions the conductive component within the connector housing.

Preferably, in the electrical connector said above, the plugin is a metal plate.

Preferably, in the electrical connector said above, the circuit board has a non-grounded circuit connecting structure and a grounded circuit connecting structure. The internal terminal transmitting structure is joined to the non-grounded circuit connecting structure and electrically connected to the non-grounded circuit layer. The external terminal transmitting structure is joined to the grounded circuit connecting structure and electrically connected to the grounded circuit layer.

Preferably, in the electrical connector said above, the electrical connector is also used for joining a joining component, which is respectively joined to the non-grounded circuit connecting structure and the grounded circuit connecting structure, and electrically connected to the non-grounded circuit layer and the grounded circuit layer, respectively.

Compared to prior art, the electrical connector provided in this application replaces the use of the conductive wire to transmit signals with the circuit board to allow the conductive component of the electrical connector to transmit signals without the need for the conductive wire. This addresses the known issue in manufacturing electrical connectors where it is challenging to maintain a fixed relative position between conductive components and conductive wires. The use of a circuit board enables automated production of the electrical connector, ultimately reducing manufacturing costs.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a three-dimensional schematic diagram of an embodiment of the electrical connector of the present application.

FIG. 2 is an exploded schematic diagram of some components of an embodiment of the electrical connector of the present application.

FIG. 3 is an exploded schematic diagram of some components of an embodiment of the electrical connector of the present application.

FIG. 4 is a three-dimensional schematic diagram of some components of an embodiment of the electrical connector of the present application.

FIG. 5 is a three-dimensional schematic diagram of some components of an embodiment of the electrical connector of the present application.

FIG. 6 is a three-dimensional schematic diagram of some components of an embodiment of the electrical connector of the present application.

FIG. 7 is a three-dimensional schematic diagram of some components of an embodiment of the electrical connector of the present application.

FIG. 8 is a three-dimensional schematic diagram of some components of an embodiment of the electrical connector of the present application.

FIG. 9 is a three-dimensional schematic diagram of some components of an embodiment of the electrical connector of the present application.

FIG. 10 is a rear view schematic diagram of an embodiment of the electrical connector of the present application.

FIG. 11 is a sectional schematic diagram of some components of the electrical connector shown in FIG. 10 along line AA.

FIG. 12 is a sectional schematic diagram of some components of the electrical connector shown in FIG. 10 along line BB.

FIG. 13 is a three-dimensional schematic diagram of an embodiment of the electrical connector of the present application.

FIG. 14 is a rear view schematic diagram of an embodiment of the electrical connector of the present application.

FIG. 15 is a sectional schematic diagram of some components of the electrical connector shown in FIG. 14 along line CC.

FIG. 16 is a sectional schematic diagram of some components of the electrical connector shown in FIG. 14 along line DD.

FIG. 17 is a side view schematic diagram of an embodiment of the electrical connector of the present application.

FIG. 18 is a sectional schematic diagram of some components of the electrical connector shown in FIG. 17 along line EE.

FIG. 19 is a three-dimensional schematic diagram of an embodiment of the electrical connector of the present application.

FIG. 20 is a three-dimensional schematic diagram of an embodiment of the electrical connector of the present application.

FIG. 21 is a three-dimensional schematic diagram of an embodiment of the electrical connector of the present application.

FIG. 22 is a rear view schematic diagram of an embodiment of the electrical connector of the present application.

FIG. 23 is a sectional schematic diagram of some components of the electrical connector shown in FIG. 22 along line GG.

FIG. 24 is a sectional schematic diagram of some components of the electrical connector shown in FIG. 22 along line FF.

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

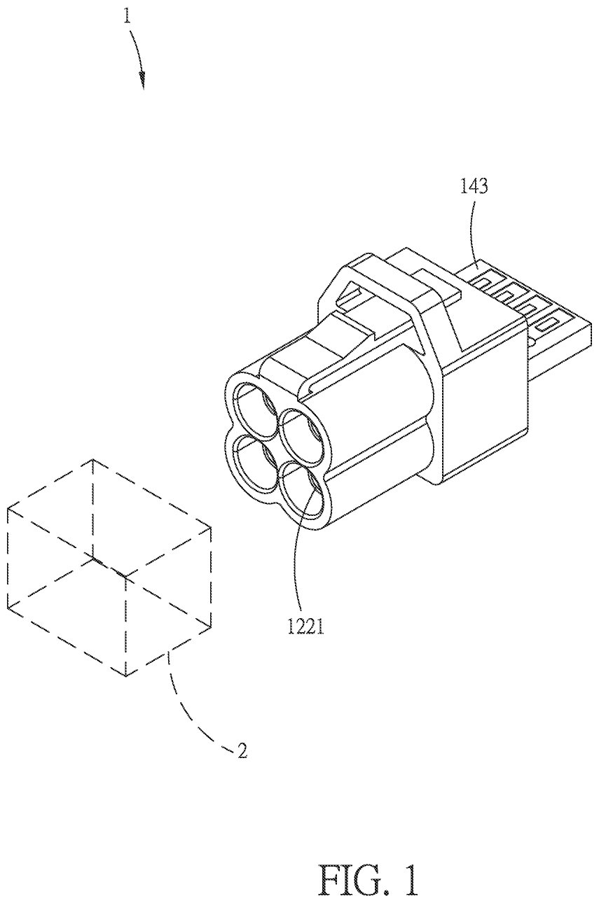

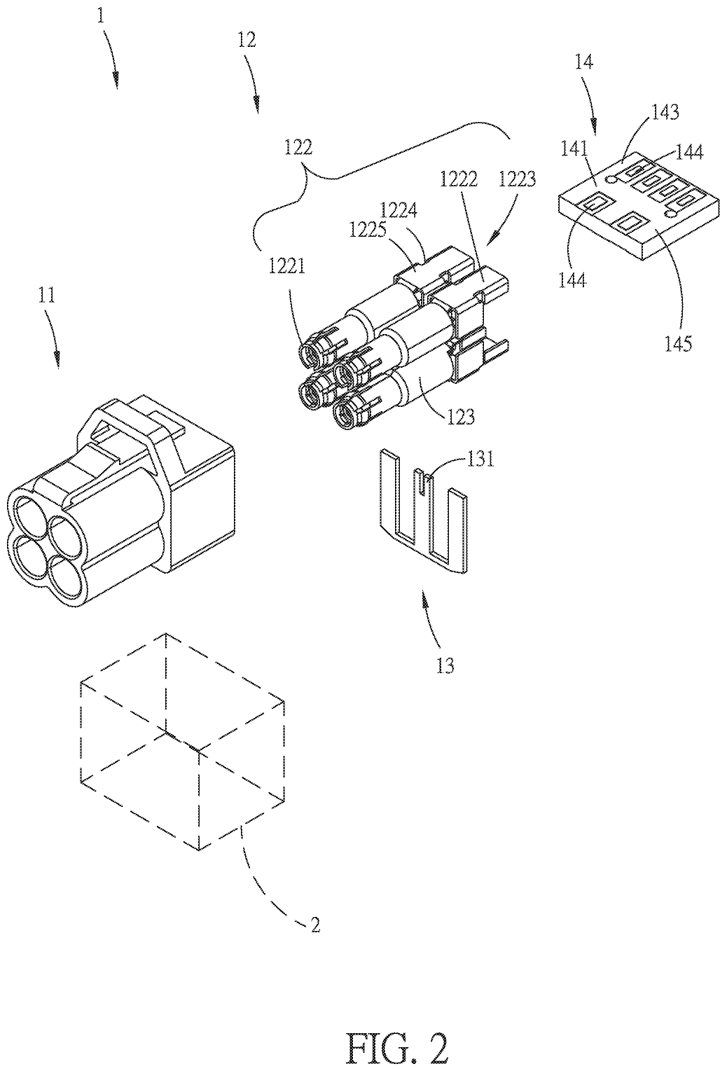

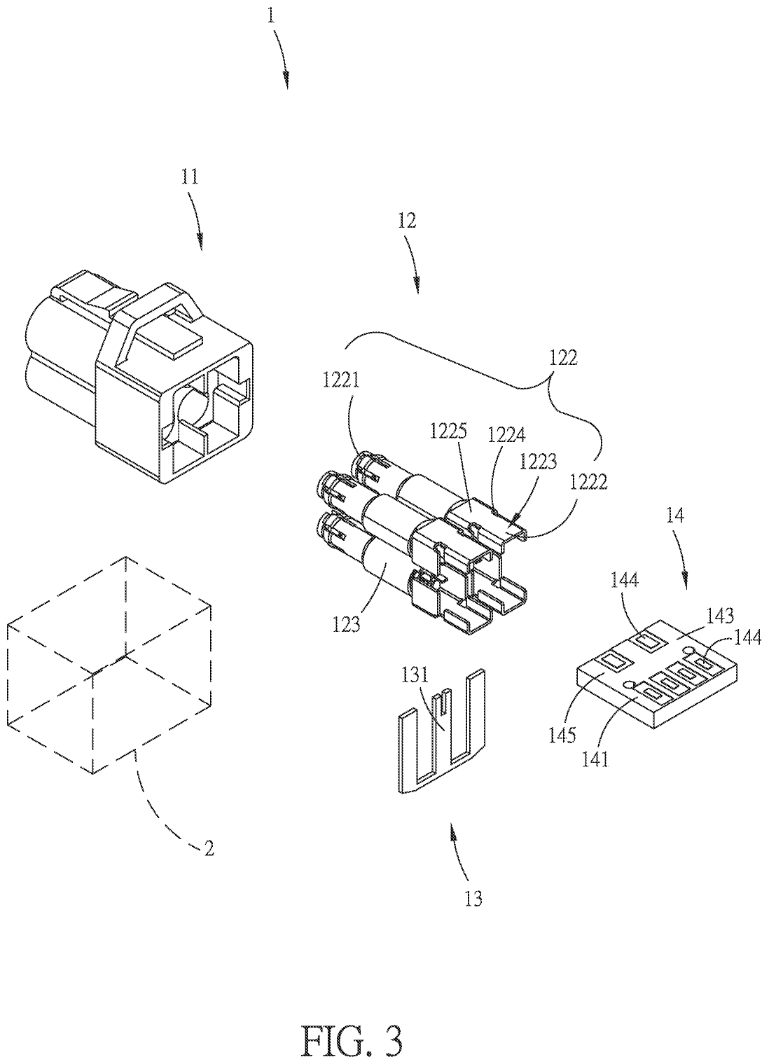

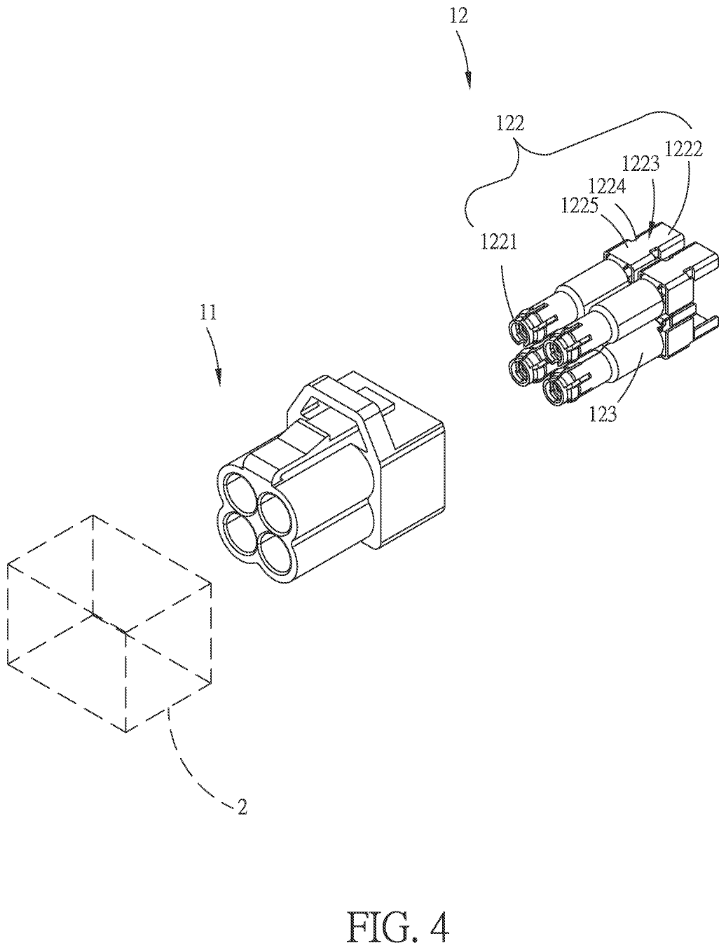

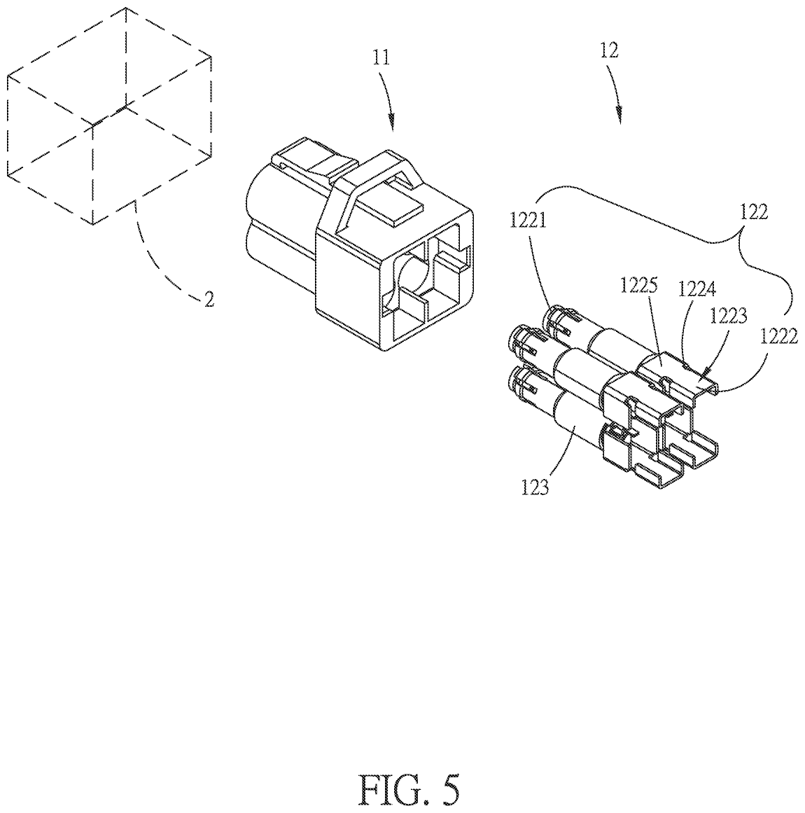

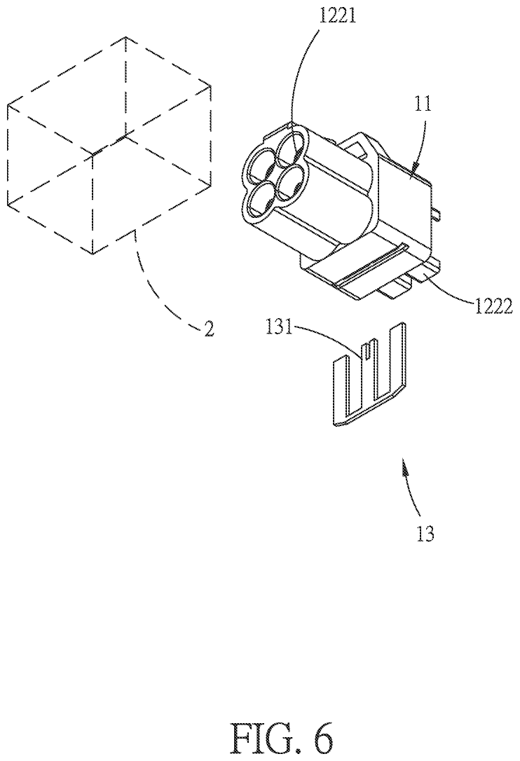

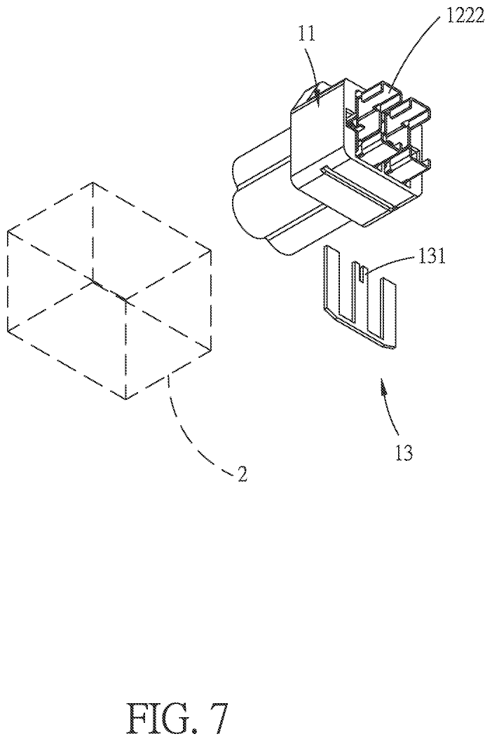

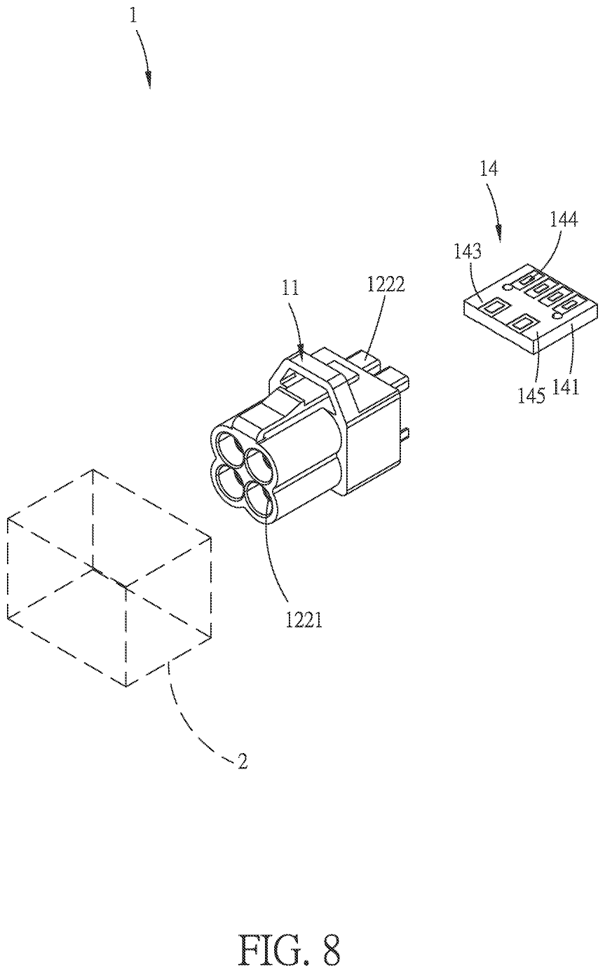

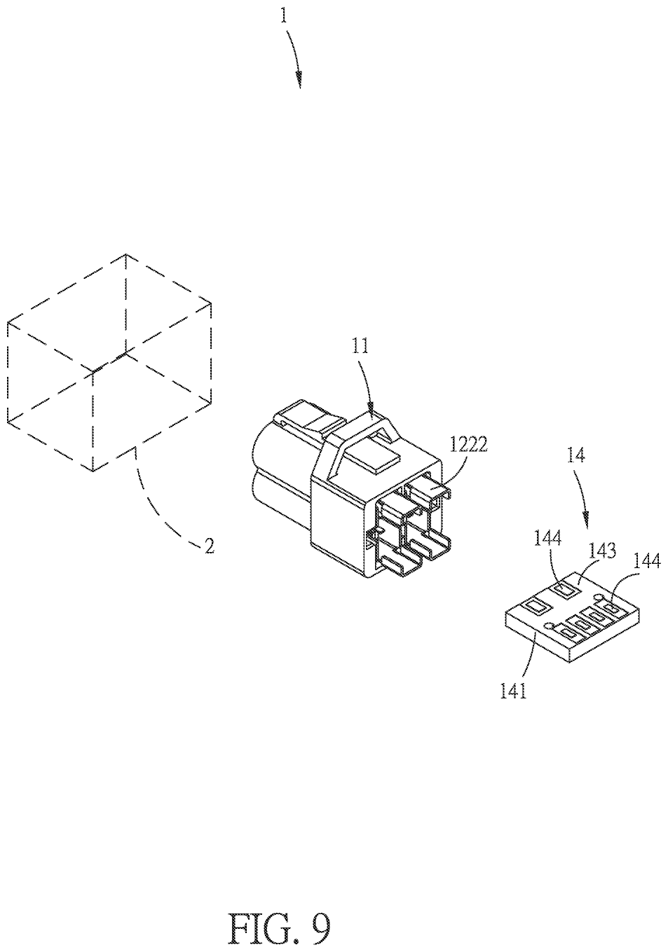

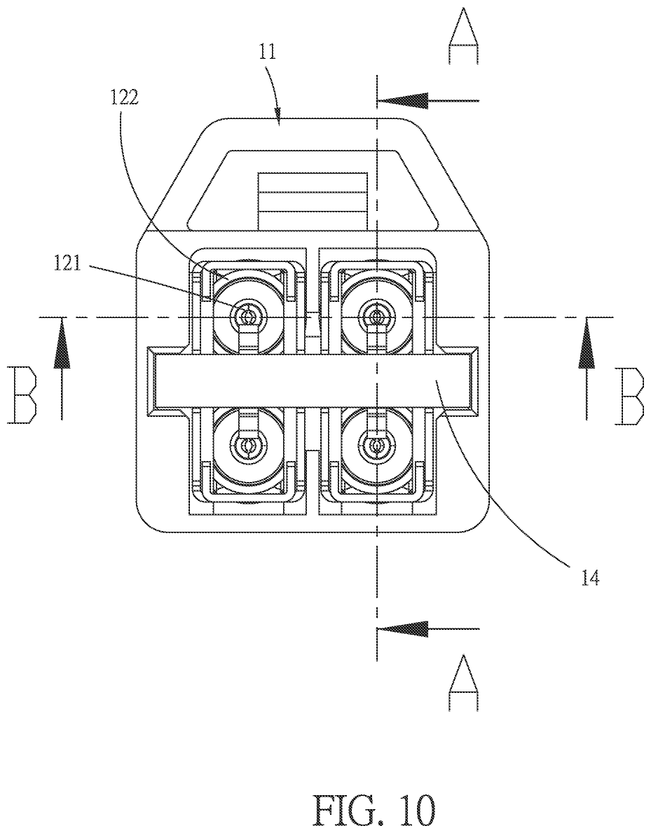

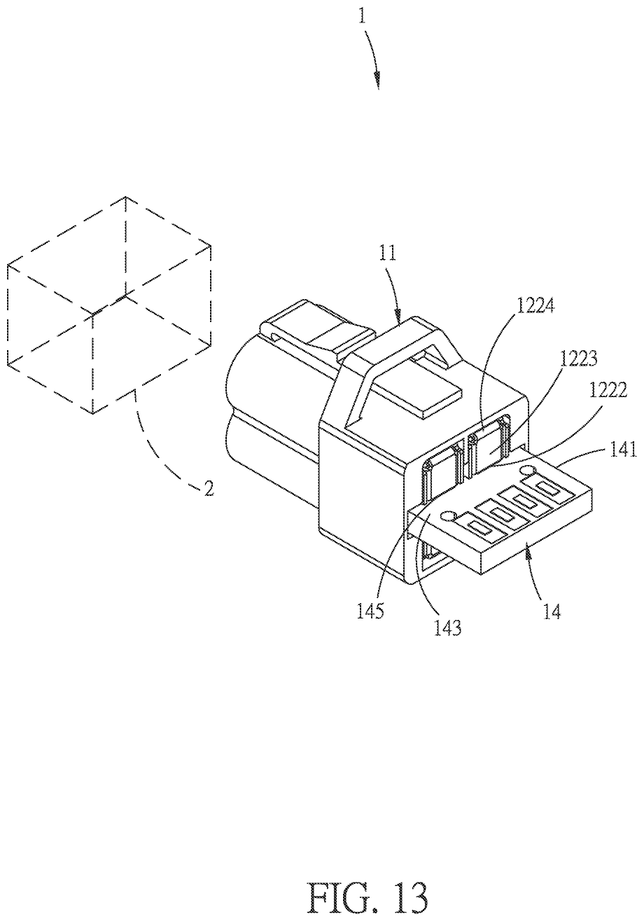

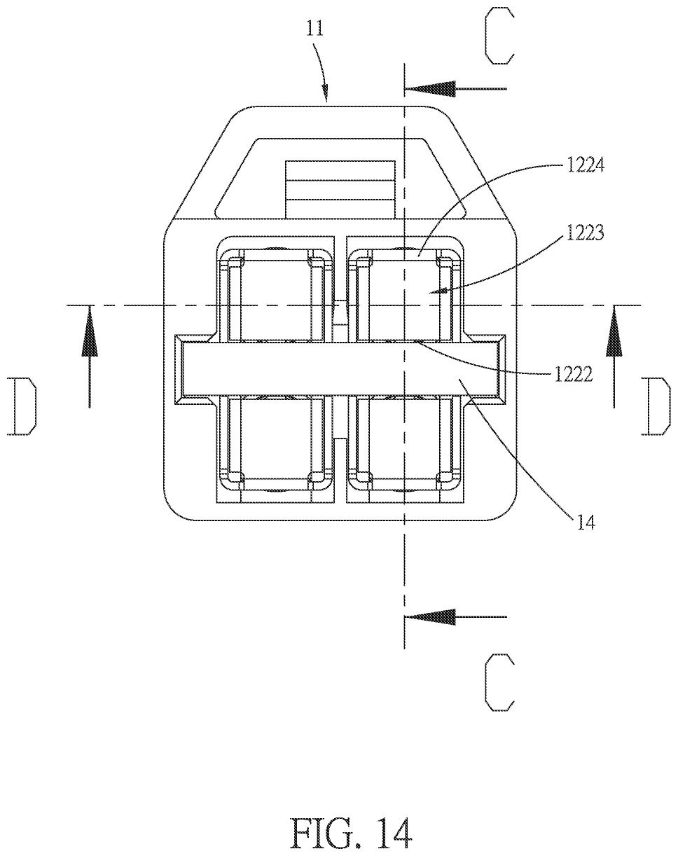

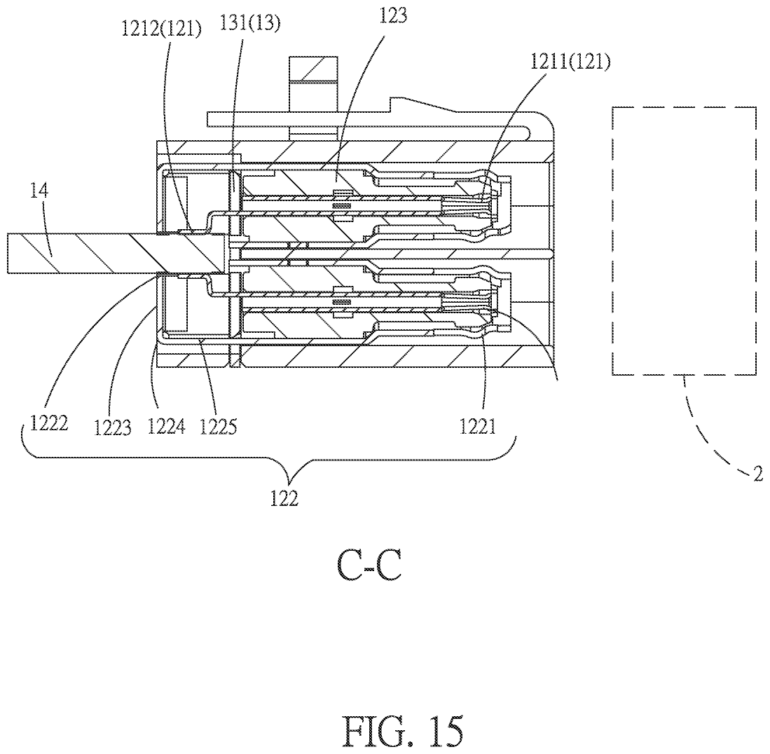

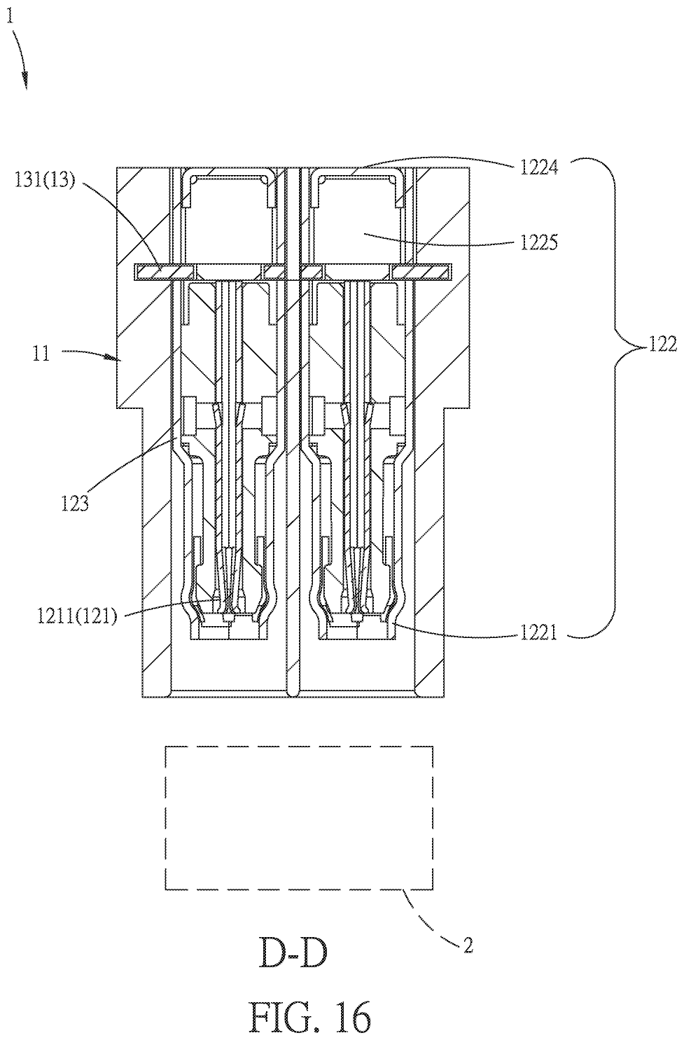

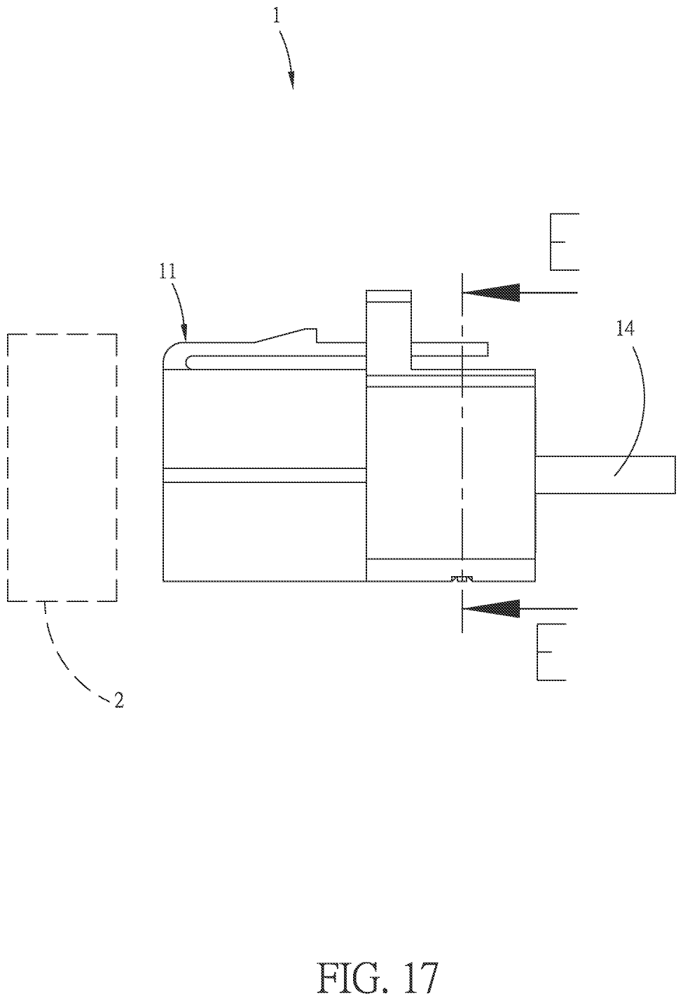

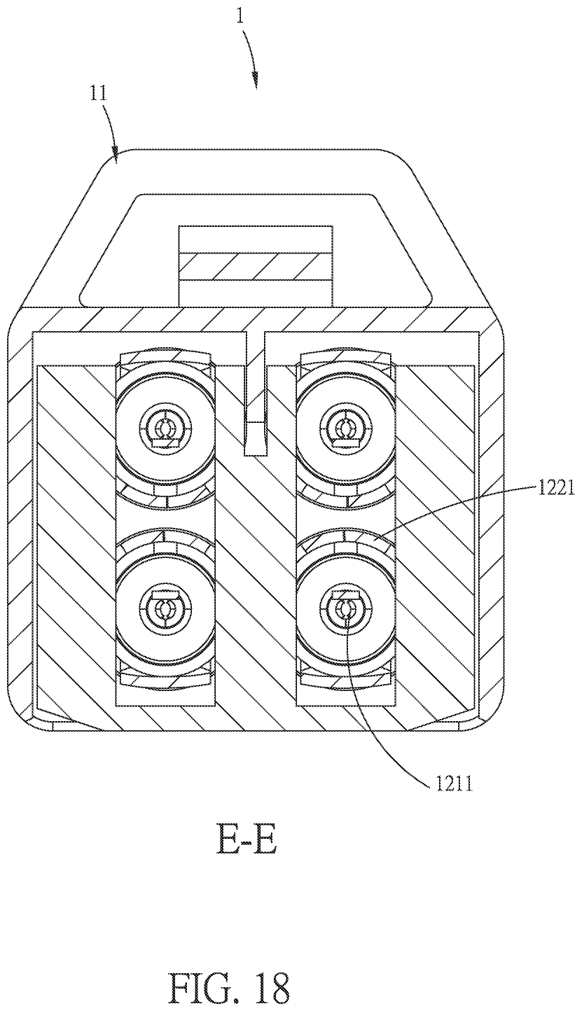

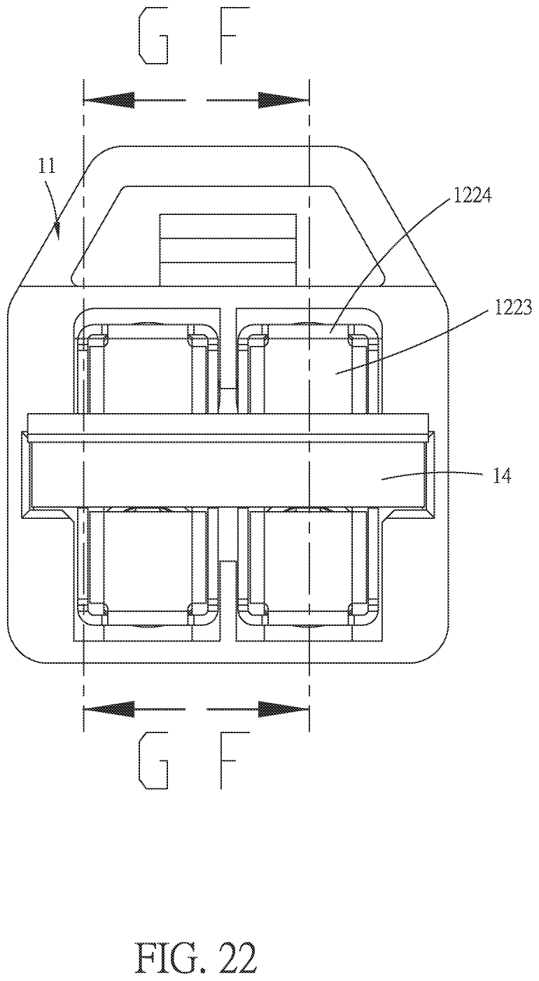

Technical features of the present application are described with reference to FIGS. 1 to 24 and the following embodiments.

The present invention provides an electrical connector, such as an FAKRA electrical connector, which can be used for joining with a joining component and transmit ground signals and non-ground signals to the joining component without the use of conductive wires. As shown in the embodiments from FIGS. 1 to 9, the electrical connector 1 comprises a connector housing 11, a conductive components 12, a plugin 13, and a circuit board 14. The connector housing 11 is an insulator with multiple slots, and multiple slots allow the conductive components 12, the plugin 13, and the circuit board 14 to be inserted into the connector housing 11. This enables the conductive components 12, plugin 13, and circuit board 14 to be individually connected to the connector housing 11. Therefore, the connector housing 11 provides positioning for the conductive components 12, the plugin 13, and the circuit board 14, addressing the issue of difficulty in fixing the relative positions of the conductive components 12, the plugin 13, and the circuit board 14 to allow for the automated production of the electrical connector 1, leading to a reduction in manufacturing costs.

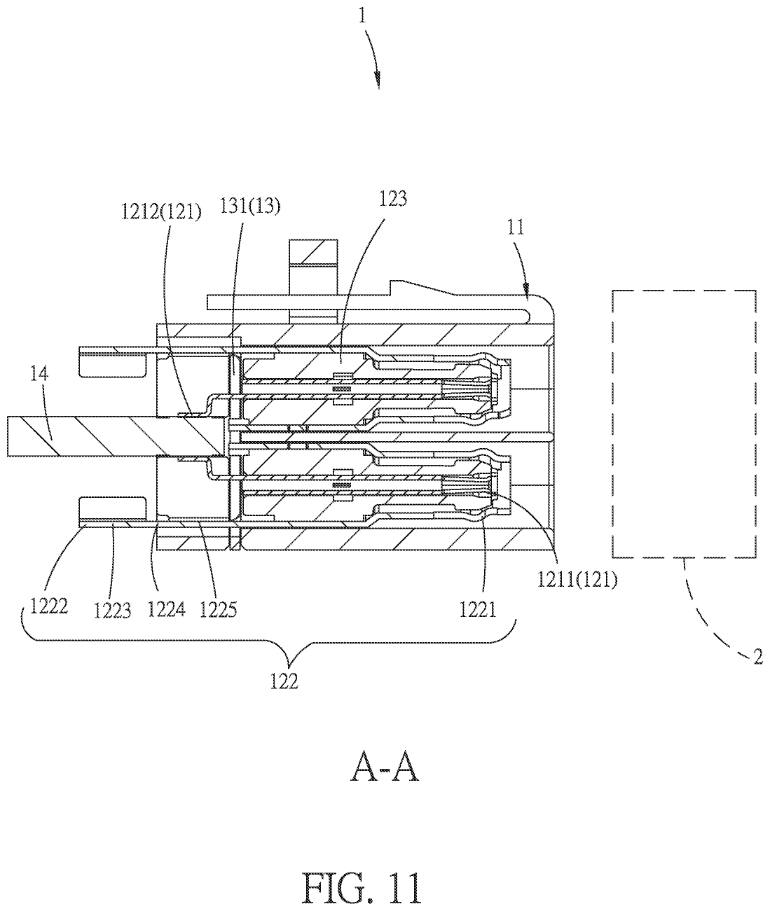

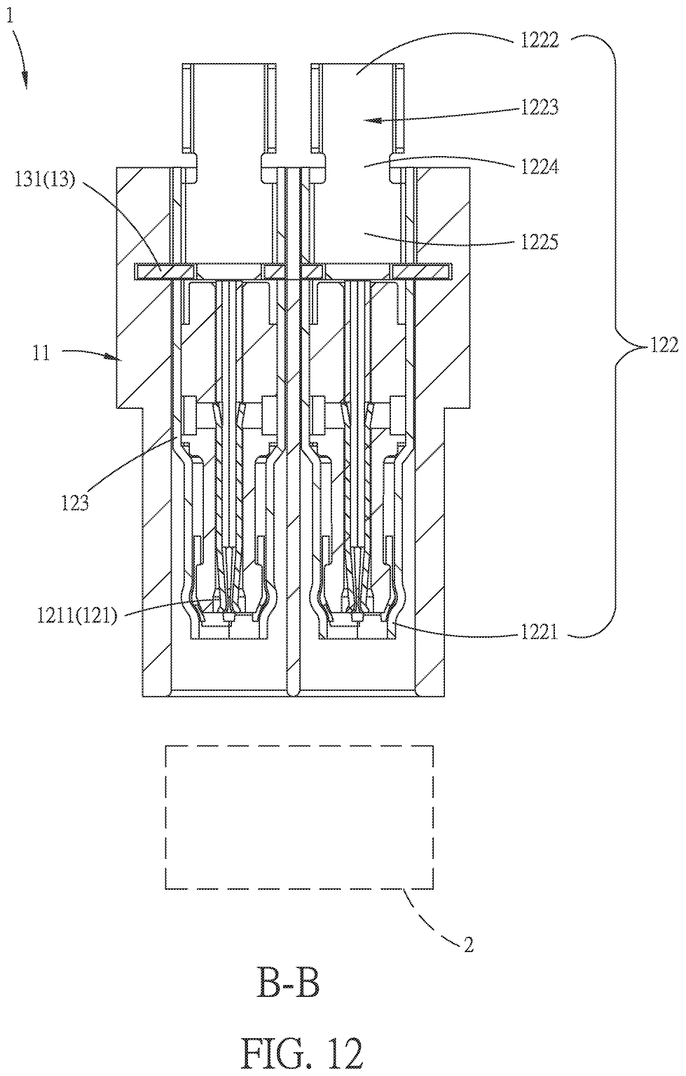

As shown in the embodiments of FIG. 11 to FIG. 12, the conductive component 12 comprises an internal terminal 121, an external terminal 122, and a conductive component housing 123. The conductive component housing 123 is, for example, an insulator and can separate the internal terminal 121 from the external terminal 122. The plugin 13 is, for example, a metal sheet-like body and has a plugin positioning structure 131. When the plugin 13 is inserted into the connector housing 11, the plugin positioning structure 131 is embedded in the conductive component housing 123 of the conductive component 12 and positioned within the connector housing 11. This addresses the issue of fixing the position of the conductive component 12, enabling automated production of the electrical connector 1, and consequently reducing production costs of the electrical connector 1.

It should be noted that the electrical connector 1 comprises a plurality of the conductive components 12, and the plugin 13 is embedded in the plurality of the conductive components 12, positioning and isolating them within the connector housing 11. This prevents interference, such as crosstalk interference, from occurring when the plurality of the conductive components 12 transmit signals, ensuring that the electrical connector 1 is less susceptible to interference attenuation during signal transmission.

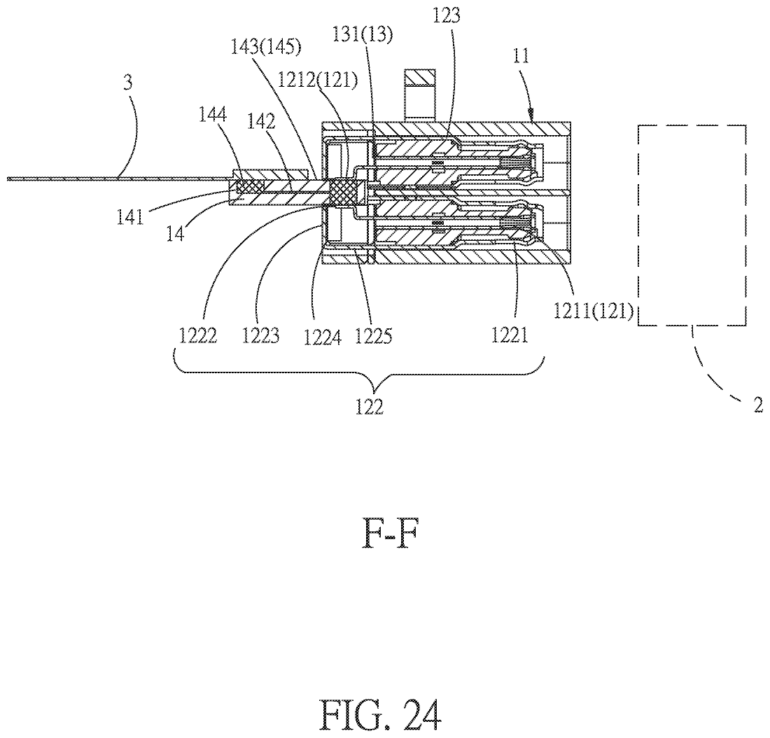

In the embodiment shown in FIG. 24, the internal terminal 121 comprises an internal terminal joining structure 1211 and an internal terminal transmitting structure 1212. The external terminal 122 comprises an external terminal joining structure 1221 and an external terminal transmitting structure 1222. In this embodiment, the circuit board 14 includes a circuit board body 141, a non-grounded circuit layer 142, a grounded circuit layer 143, a non-grounded circuit connecting structure 144, and a grounded circuit connecting structure 145. The non-grounded circuit layer 142 is located in the inner layer of the circuit board body 141, and the grounded circuit layer 143 is located in the outer layer of the circuit board body 141, allowing the grounded circuit layer 143 to provide electrical shielding for the transmission of signals from the non-grounded circuit layer 142 to prevent interference, such as crosstalk interference, from affecting the non-grounded circuit layer 142 during signal transmission, ensuring that the electrical connector 1 is less susceptible to interference attenuation during signal transmission.

It should be noted that the internal terminal joining structure 1211 and the external terminal joining structure 1221 are provided for separately joining with the joining component 2 for signal transmission. The internal terminal transmitting structure 1212 is electrically connected to the internal terminal joining structure 1211 and is connected to the non-grounded circuit connecting structure 144 to be electrically connected with the non-grounded circuit layer 142. This enables non-grounded signals to be transmitted to the joining component 2 through the non-grounded circuit layer 142 and the internal terminal joining structure 1211 without the need for conductive wires. Additionally, the external terminal transmitting structure 1222 electrically connects the external terminal joining structure 1221 and connects to the grounded circuit connecting structure 145 to electrically connect with the grounded circuit layer 143 to allow grounded signals to be transmitted to the joining component 2 through the grounded circuit layer 143 and the external terminal joining structure 1221 without the need for conductive wires.

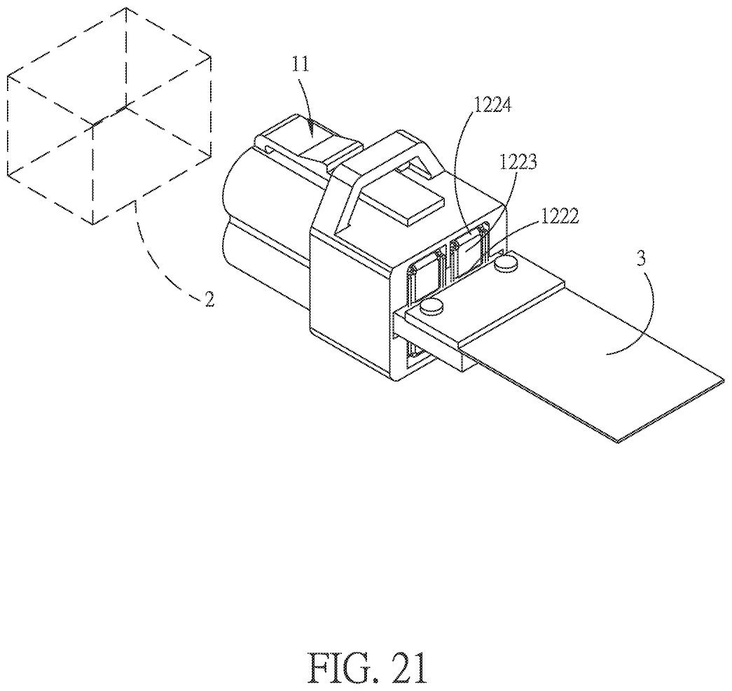

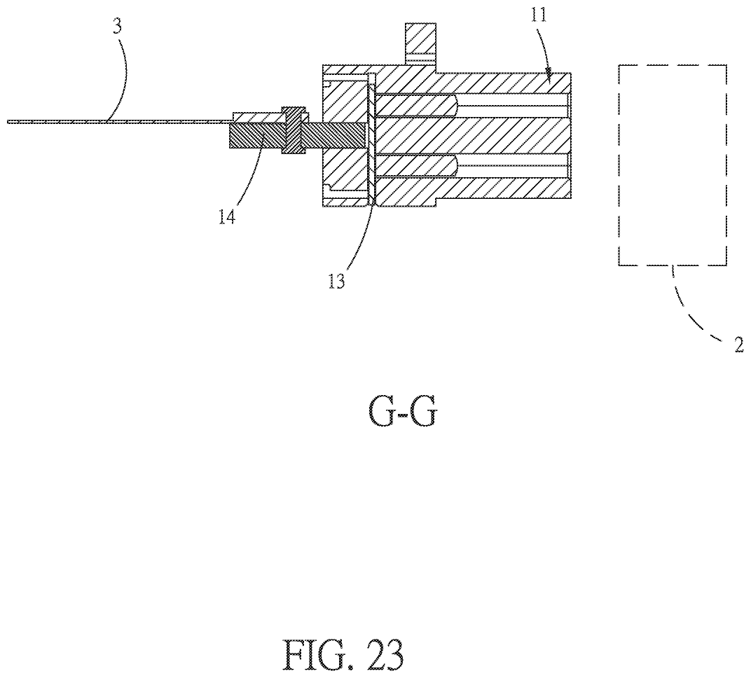

As shown in the embodiments of FIG. 21, FIG. 23, and FIG. 24, the electrical connector 1 is connected to a connecting component 3, which can serve as a signal transmission component. The connecting component 3 can be connected to the non-grounded circuit connecting structure 144, thereby being electrically connected with the non-grounded circuit layer 142 to allow the non-grounded signals of the connecting component 3 to be transmitted to the joining component 2 through the non-grounded circuit layer 142 and the internal terminal joining structure 1211 without the need for conductive wires. Additionally, the connecting component 3 can also be connected to the grounded circuit connecting structure 145, thereby electrically connecting with the grounded circuit layer 143 to enable the grounded signals of the connecting component 3 to be transmitted to the joining component 2 through the grounded circuit layer 143 and the external terminal joining structure 1221 without the need for conductive wires.

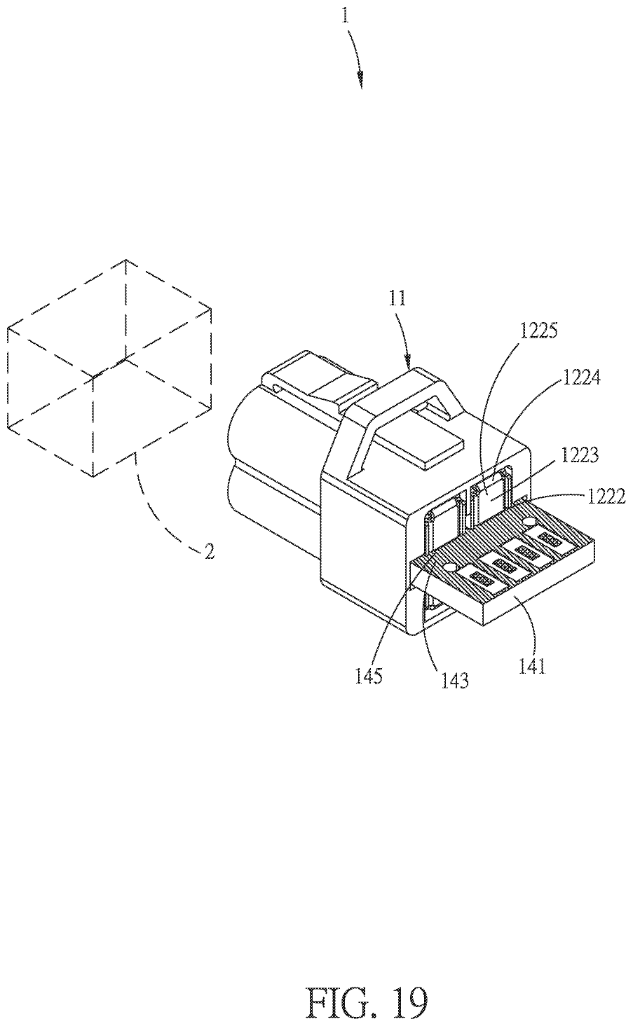

As shown in FIG. 19 to FIG. 24, the external terminal 122 also has an external terminal shielding structure 1223, which is, for example, a U-shaped structure enabling to shield the internal terminal transmitting structure 1212 in at least three directions, and providing electrical shielding for the signal transmission of the internal terminal transmitting structure 1212 to prevent interference from external factors, such as crosstalk during the transmission of signals. Consequently, the internal terminal transmitting structure 1212 would not be prone to interference and signal attenuation during signal transmission.

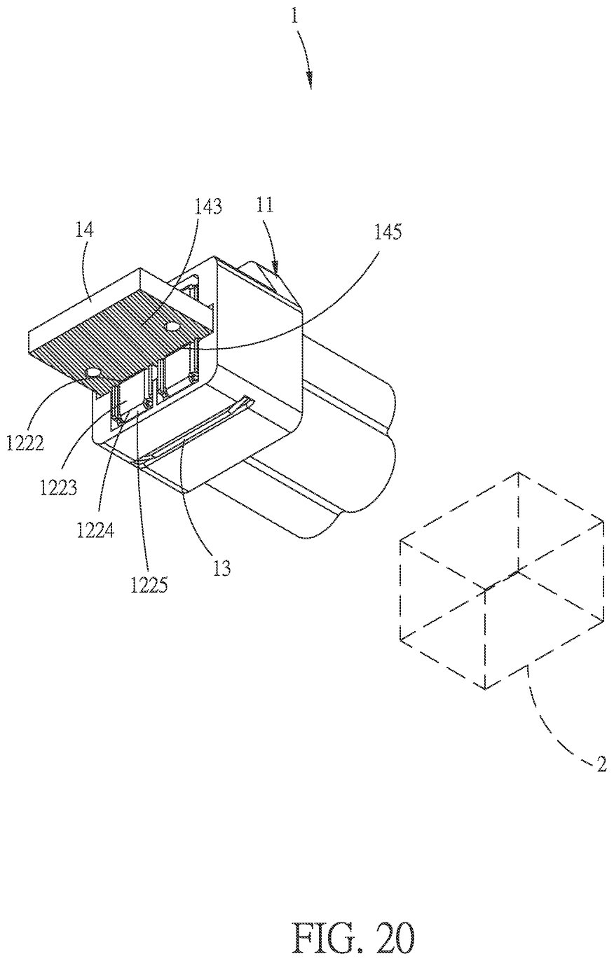

In the embodiments shown in FIG. 19 to FIG. 20, the external terminal 122 has an external terminal bending structure 1224 and an external terminal body 1225. The external terminal bending structure 1224 is connected to the external terminal body 1225 and can bend the external terminal body 1225 to form the external terminal shielding structure 1223.

It should be noted that in the electrical connector of this application, certain structural components mentioned earlier can be omitted. For example, the electrical connector includes an internal terminal and a circuit board. The internal terminal has an internal terminal joining structure and an internal terminal transmitting structure. The circuit board consists of a circuit board body and a non-grounded circuit layer. The internal terminal joining structure is provided to join to a joining component. The internal terminal transmitting structure is electrically connected to the non-grounded circuit layer and the internal terminal joining structure respectively, allowing non-grounded signals to be transmitted to the joining component through the non-grounded circuit layer and the internal terminal joining structure.

In summary, the present invention provides an electrical connector that replaces the use of the conductive wire with a circuit board for signal transmission to allow the conductive component of the electrical connector to transmit signals without relying on the conductive wire. It addresses the known issue of difficulty in fixing the relative positions of the conductive component and the conductive wire during electrical connector manufacturing. This innovation enables automated production of the electrical connector and to reduce production costs of the electrical connector.

The examples above are only illustrative to explain principles and effects of the invention, but not to limit the invention. It will be apparent to those skilled in the art that modifications and variations can be made without departing from the spirit and scope of the invention. Therefore, the protection range of the rights of the invention should be as defined by the appended claims.

What is claimed is:

1. An electrical connector for joining with a joining component and capable of transmitting a non-grounded signal to the joining component, comprising:
an internal terminal, including an internal terminal joining structure and an internal terminal transmitting structure;
a circuit board, including a circuit board body and a non-grounded circuit layer;
wherein the internal terminal joining structure is provided to join to the joining component;
wherein the internal terminal transmitting structure is electrically connected to the non-grounded circuit layer and the internal terminal joining structure respectively, allowing the non-grounded signal can be transmitted to the joining component via the non-grounded circuit layer and the internal terminal joining structure.

2. The electrical connector of claim 1, a grounded signal can further be transmitted to the joining component, wherein the circuit board further includes a grounded circuit layer, and the electrical connector further comprises: an external terminal including an external terminal joining structure and an external terminal transmitting structure;
the external terminal joining structure is provided to join to the joining component;
the external terminal transmitting structure is electrically connected to the grounded circuit layer and the external terminal joining structure respectively, allowing the grounded signal can be transmitted to the joining component via the grounded circuit layer and the external terminal joining structure.

3. The electrical connector of claim 2, wherein the non-grounded circuit layer is located on the inner layer of the circuit board body and the grounded circuit layer is located on the outer layer of the circuit board body, allowing the grounded circuit layer can provide electrical shielding for the signal transmission of the non-grounded circuit layer.

4. The electrical connector of claim 2, wherein the external terminal further includes an external terminal shielding structure that shields the internal terminal transmitting structure, allowing the external terminal shielding structure can provide electrical shielding for the signal transmission of the internal terminal transmitting structure.

5. The electrical connector of claim 4, wherein the external terminal shielding structure is a U-shaped structure and can shield the internal terminal transmitting structure in three directions.

6. The electrical connector of claim 4, wherein the external terminal further includes an external terminal bending structure and an external terminal body, and the external terminal bending structure is placed on the external terminal body for bending the external terminal body to form the external terminal shielding structure.

7. The electrical connector of claim 2, further comprises: a connector housing, at least a conductive component and a plugin;
wherein the conductive component, the plugin and the circuit board are plugged into the connector housing separately, and the conductive component includes the internal terminal and the external terminal;
the plugin includes a plugin positioning structure embedded in the conductive component for positioning the conductive component in the connector housing.

8. The electrical connector of claim 7, wherein at least a conductive component is a plurality of conductive components, and the plugin is embedded in the plurality of conductive components for positioning and separating the plurality of conductive components in the connector housing.

9. The electrical connector of claim 7, wherein the conductive component includes a conductive component housing that separates the internal terminal and the external terminal, and the plugin positioning structure is embedded in the conductive component housing for positioning the conductive component in the connector housing.

10. The electrical connector of claim 7, wherein the plugin is a metal sheet.

11. The electrical connector of claim 2, wherein the circuit board includes a non-grounded circuit connecting structure and a grounded circuit connecting structure, and the internal terminal transmitting structure is connected to the non-grounded circuit connecting structure and electrically connected to the non-grounded circuit layer, and the external terminal transmitting structure is connected to the grounded circuit connecting structure and electrically connected to the grounded circuit layer.

12. The electrical connector of claim 11, wherein the electrical connector is further used to connect a connecting component, which is respectively connected to the non-grounded circuit connecting structure and the grounded circuit connecting structure and respectively electrically connected to the non-grounded circuit layer and the grounded circuit layer.
